(19) United States
(12) Patent Application Publication
(10) Pub. No.: US 2017/0215305 A1
(43) Pub. Date: Jul. 27, 2017

(54) EMI SHIELD FOR AN ELECTRONIC OPTICAL DEVICE

(71) Applicants: Raymond Kirk Price, Redmond, WA (US); Ravi Kiran Nalla, San Jose, CA (US)

(72) Inventors: Raymond Kirk Price, Redmond, WA (US); Ravi Kiran Nalla, San Jose, CA (US)

(21) Appl. No.: 15/007,568

(22) Filed: Jan. 27, 2016

(51) Int. Cl. H05K 9/00; G01B 11/14; H01S 5/02; G01B 11/22; H01S 5/022; G02B 27/01

(52) U.S. Cl. CPC H05K 9/0032; H01S 5/02248; G02B 27/0176; H01S 5/0215; G01B 11/22; G01B 11/14; G02B 2027/0178

(57) ABSTRACT

A system and method are disclosed for shielding EMI in an electronic device such as a depth sensor used in a head mounted display device. In embodiments, the shield has a dual construction including a fence that may be surface mounted to a substrate over a first set of surface mounted components. The EMI shield may further comprise a cover, which may be glued to the fence after a second set of components is mounted to the substrate.

### BACKGROUND

Head mounted display devices used for example in augmented reality environments often use a depth sensor for sensing distances to objects within the field of view of a head mounted display device. Such depth sensors often employ one or more laser diode assemblies and associated electronic components mounted on a printed circuit board for emitting laser light. Emitted light bounces of objects and is reflected back in the depth sensor, to indicate distances to the objects, for example using time of flight between light emission and receipt of reflected light.

The laser diode assemblies and associated electronic components in such devices emit electromagnetic interference (EMI), which must be shielded in order to comply with FCC regulations. One difficulty in providing EMI shielding in depth sensors such as used on head mounted display devices is that the shielding must not cover the aperture(s) through which the laser light is emitted. A further difficulty is that shielding applied over the laser diode assembly cannot be surface mounted to the printed circuit board, as the heat required for such surface mounting may damage the laser diode assembly. Another difficulty in providing shielding for depth sensors used for example in head mounted display devices is that space is at a premium, and conventional EMI shields tend to be bulky.

### SUMMARY

Embodiments of the present technology relate to an EMI shield and method of its manufacture. Embodiments of the EMI shield may be used in a light emitting optical device having a compact design, such as for example a depth sensor used in a head mounted display device presenting an augmented reality environment. The EMI shield may have a dual-piece construction. A first piece, referred to herein as the fence, may be surface mounted to a printed circuit board to cover electronic components that may also be surface mounted to the printed circuit board. The fence includes one or more openings to allow top-down connection of a light emitter such as a laser diode onto the printed circuit board. The one or more openings also allow light to leave the light emitter without obstruction.

After connection of the light emitter, a second piece of the EMI shield, referred to herein as the cover, may be affixed to the fence over portions of the light emitter and electronic components to shield EMI from the light emitter and components. The light emitter may be sensitive to high temperatures. Thus, the cover may be affixed to the fence by methods other than surface mounting which use high temperatures for solder reflow, such as for example using an adhesive. The shield is provided to allow light to leave the light emitter without obstruction.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 is an illustration of a virtual reality environment including real and virtual objects.

FIG. 2 is a perspective view of one embodiment of a head mounted display unit.

FIG. 3 is a top view of a portion of a conventional depth sensor.

FIG. 4 is a top view of a portion of a depth sensor including a pair of EMI shields according to embodiments of the present technology.

FIG. 5 is a flowchart illustrating steps for the assembly of electronic circuitry and an EMI shield according to embodiments of the present technology.

FIG. 6 is a perspective view of a portion of a printed circuit board for an electronic device at a first stage during fabrication.

FIG. 7 is a perspective view of a portion of a printed circuit board and EMI shield fence for an electronic device at a second stage during fabrication.

FIG. 8 is a top perspective view of a fence of an EMI shield according to embodiments of the present technology.

FIG. 9 is a bottom perspective view of a fence of an EMI shield according to embodiments of the present technology.

FIG. 10 is a perspective view of a portion of a printed circuit board, EMI shield fence and light emitter for an electronic device at a third stage during fabrication.

FIG. 11 is a perspective view of a portion of a printed circuit board and EMI shield for an electronic device at a fourth stage during fabrication.

### DETAILED DESCRIPTION

Embodiments of the present technology will now be described with reference to the figures, which in general relate to an EMI shield used to prevent electromagnetic radiation from an electronic device such as a compact, light-emitting optical device. Embodiments of the EMI shield may comprise two pieces: a fence and a cover. The fence may be surface mounted to a printed circuit board to cover electronic components also surface mounted to the printed circuit board. The fence may include one or more openings which provide top-down access to the printed circuit board for mounting of additional electronic components. The cover may be affixed to the fence after mounting of the additional electronic components, for example by an adhesive.

In embodiments explained below, the EMI shield may be used in association with a laser diode assembly of a depth sensor for a head mounted display device presenting an augmented reality environment. In such embodiments, optical driver circuitry may be surface mounted to a printed circuit board. Thereafter, a laser diode may be connected to the printed circuit board. As the laser diode assembly is heat sensitive, surface mounting an EMI shield to the printed circuit board after mounting the laser diode may damage the laser diode. Thus, in accordance with aspects of the present technology, the EMI shield may be assembled in a two-step process. The fence may be surface mounted over the driver circuitry after surface mounting of the driver circuitry. The opening(s) in the fence provide access to the printed circuit board to allow for gluing and wire bonding of the laser diode. Thereafter, EMI cover may be affixed to the fence using an adhesive to shield the laser diode while preventing damage to the laser diode.

The fence and cover are configured to block EMI from the driver circuitry and laser diode, while allowing emission of light from the laser diode unimpeded. Additionally, the fence may be surface mounted in the same process as the surface mounting of the driver circuitry.

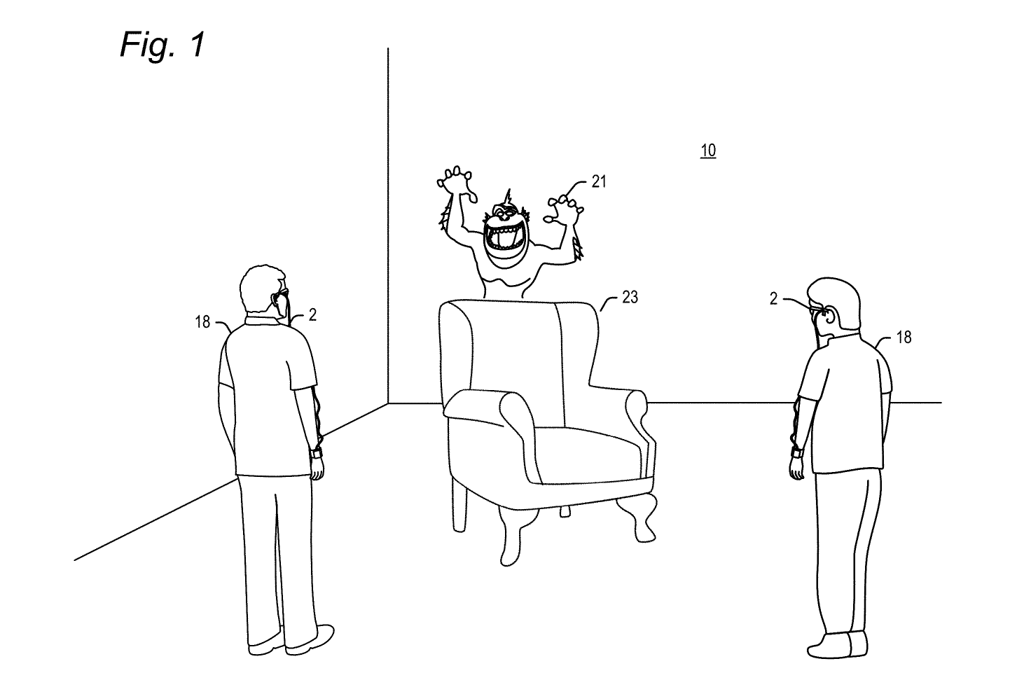

In one example, the EMI shield according to the present technology may be used in a depth sensor of a head mounted display device for presenting an augmented reality experience. FIG. 1 illustrates an augmented reality environment 10 for providing an augmented reality experience to users by fusing virtual content 21 with real content 23 within each user's FOV. FIG. 1 shows users 18 wearing a head mounted display device 2 for presenting the augmented reality experience to the users. It is understood that the particular virtual content shown in FIG. 1 is by way of example only, and may be any of a wide variety of virtual objects.

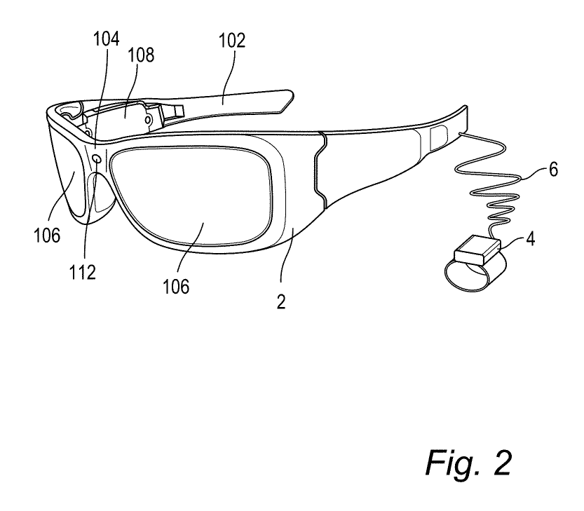

As shown in FIG. 2, a head mounted display device 2 may include glasses frame 102 and a nose bridge 104 so that the head mounted display device 2 may be worn comfortably on a user's head. The device 2 may further include optical assemblies 106 including lenses and optical wave guides for presenting real and virtual objects to the eyes of a wearer. Control circuits 108 may be mounted in the frame 102 to provide various electronics that support the components of head mounted display device 2. The head mounted display device 2 may include or be in communication with its own processing unit 4, for example via a flexible wire 6.

The head mounted display device may further include a room facing camera 112 which may be or include a depth sensor, as explained in greater detail below. Additional components of the head mounted display device used to generate an augmented reality experience but not directly related to the EMI shield of the present technology are omitted. However, such additional components are described for example in U.S. Patent Publication No. 2013/0326364 entitled “Position Relative Hologram Interactions,” published on Dec. 5, 2013.

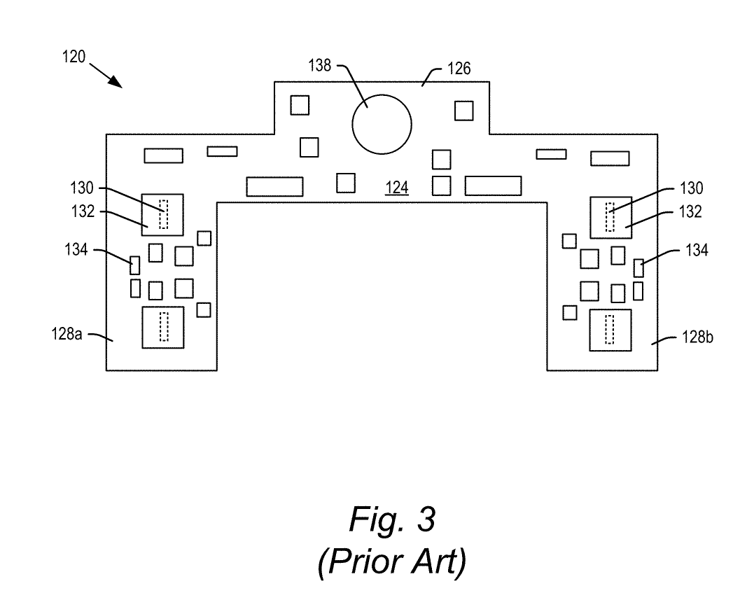

FIG. 3 is a schematic diagram of a conventional depth sensor 120 that may be used in room facing camera 112. Depth sensor 120 includes a substrate such as a printed circuit board (PCB) 124 including a central portion 126 and a pair of opposed edge portions 128a, 128b (collectively, edge portions 128). The edge portions 128 each include a pair of light emitters 130 within mirror/lens assemblies 132. While two light emitters 130 are shown in each edge portion 128, there may be one, or more than two, in each edge portion 128 in further embodiments. Instead of separate edge portions, further configurations may include one or more light emitters 130 centrally located on the PCB 124. The light emitters 130 may be semiconductor devices such as for example laser diodes. Other types light emitters are contemplated. The edge portions 128 each further include driver circuitry 134 supporting the operation of the light emitters 130. The central portion 126 of PCB 124 further includes a light sensor 138 for sensing light from the emitters 130 that is reflected back to the depth sensor 120 from objects within the field of view of the depth sensor 120.

In an example embodiment, the depth sensor 120 may be configured to capture a depth image of an area in the field of view of the sensor 120. The depth image may include a two-dimensional (2-D) pixel array of the captured area where each pixel in the 2-D pixel array may represent a distance of an object in the captured area from the depth sensor 120. The depth image may capture depth values of the area via any suitable technique including, for example, time-of-flight, structured light, stereo image, or the like. According to one embodiment, the depth sensor 120 may organize the calculated depth information into “Z layers,” or layers that may be perpendicular to a Z axis extending from the depth sensor along its line of sight.

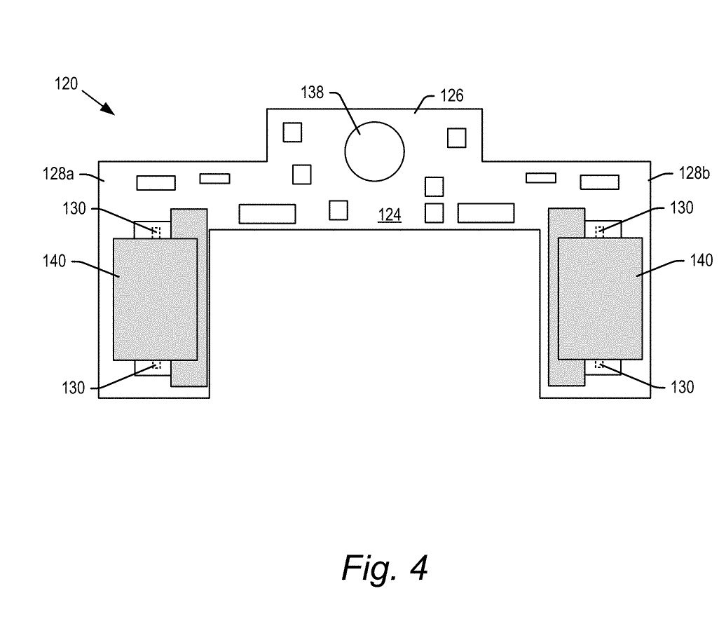

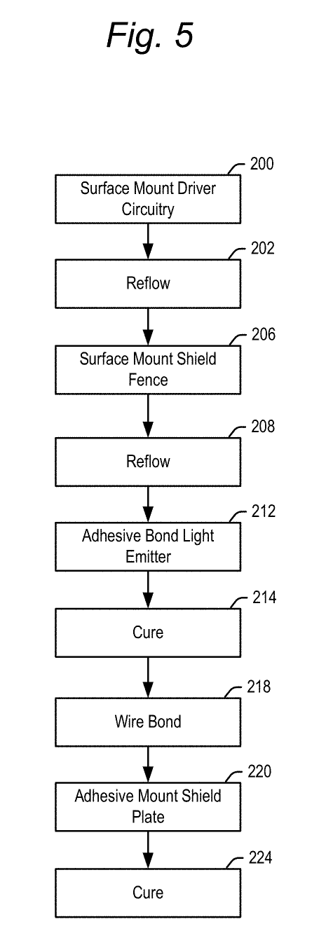

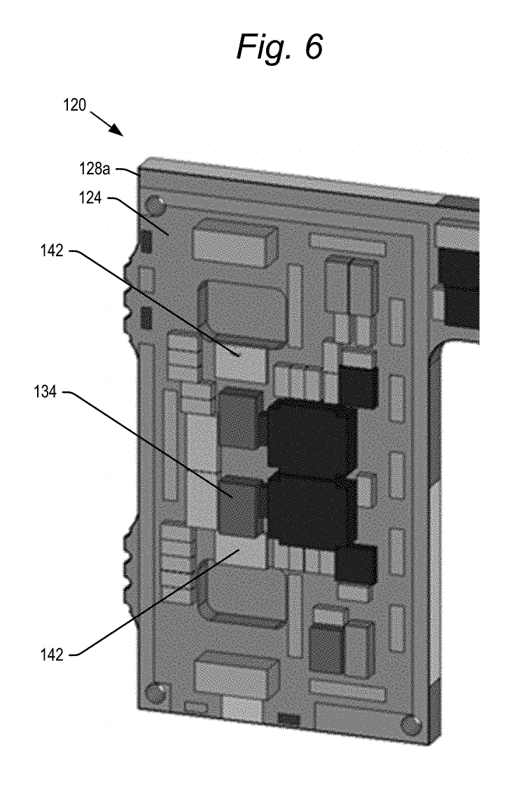

The light emitters 130 and driver circuitry 134 emit electromagnetic radiation which can interfere with the operation of other electronics in the vicinity. Therefore, in accordance with aspects of the present technology, each edge portion 128 may include an EMI shield 140 (shown shaded in FIG. 4). Further details of the EMI shield 140 are explained below with reference to the flowchart of FIG. 5 and the illustrations of FIGS. 6-11. As the edge portions 128a, 128b may be identical to each other, FIGS. 6-11 show one of the edge portions, for example edge portion 128a.

In general, a first set of electronic components may be surface mounted to the PCB 124 using heat, while a second set of electronic components such as the light emitters 130 are heat sensitive and are mounted using an adhesive after the first set of components. The EMI shield 140 may be affixed in two parts—one part being surface mounted using heat before the heat-sensitive components are affixed, and a second part being affixed using adhesive after the heat-sensitive components are affixed. In this way, the overall EMI shield 140 shields electromagnetic radiation from the first and second sets of electronic components without impeding the mounting or functionality of the heat-sensitive components.

In step 200, a first set of electronic components are surface mounted to electrical contacts of the PCB 124, using a heat-bonding material such as for example solder. The solder may be reflowed in a heating process in step 202. The first set of electronic components are those which are able to withstand surface mounting in the heating process and include for example the driver circuitry 134, one electronic component of which is marked in FIG. 6. As noted above, the driver circuitry operates in conjunction with the light emitters to controllably power the light emitters, for example in a pulsed manner. FIG. 6 also shows a pair of contact pads 142 for receiving the light emitters 130 as explained below.

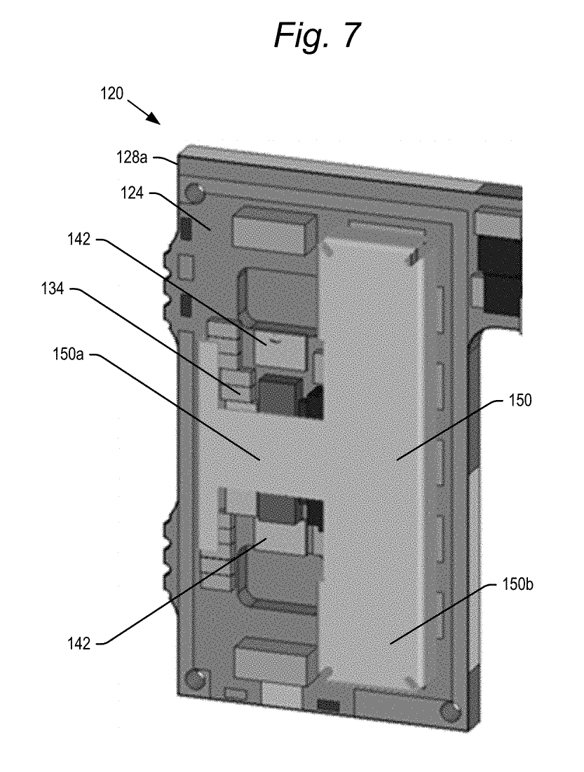

In step 206, a first part of the EMI shield 140—fence 150—may be surface mounted to contact pads or other metal portions of the PCB 124, as shown in FIG. 7. At least portions of the fence 150 may be mounted to contact pads which are electrically grounded. In general, the fence 150 has a shape which covers at least portions of the first set of electronic components, while at the same time allowing access to portions of the PCB 124 which are to receive the heat-sensitive second set of electronic components. The fence may be surface mounted to the PCB 124, using a heat-bonding material such as for example solder.

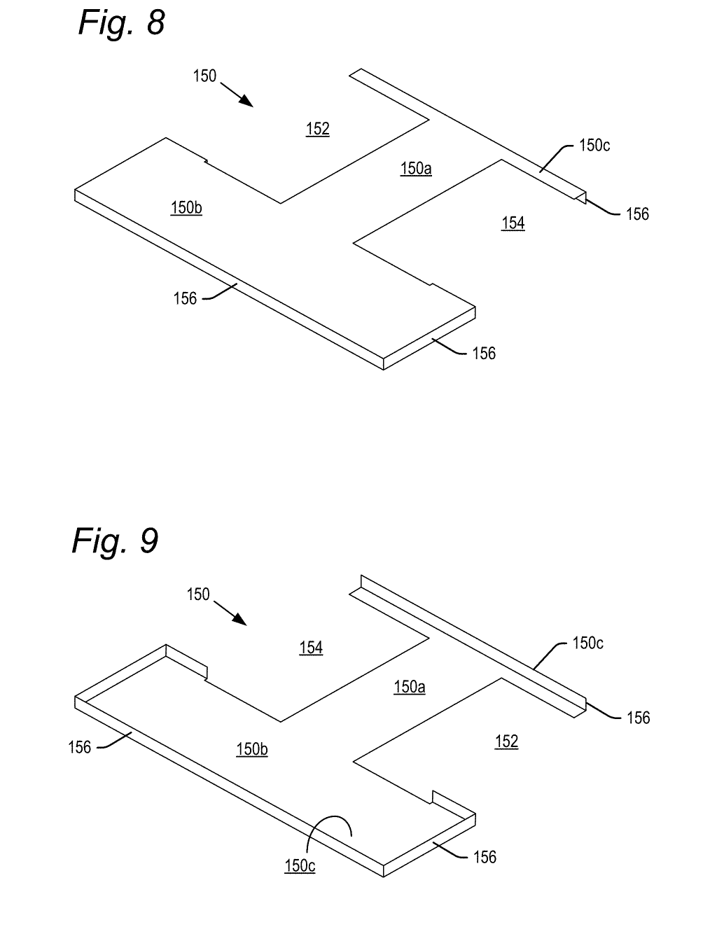

The fence 150 is shown in FIG. 7, and the top and bottom perspective views of FIGS. 8 and 9, respectively. In one embodiment, the fence may have a general “T”-shaped configuration which, as noted above, covers at least portions of the driver circuitry 134, while leaving the contact pads 142 exposed to receive the light emitters 130. The “T”-shaped configuration of FIGS. 7-9 includes a base portion 150a forming a base of the “T,” and a transverse portion 150b forming a top of the “T.” An elongate portion 150c may be formed at an end of the base portion 150a opposite the end of the base portion including the transverse portion 150b. The base portion 150a, transverse portion 150b and elongate portion 150c together shield radiation from the first set of electronic components including at least portions of the driver circuitry 134, while also defining openings 152 and 154 in the shield fence 150. The openings 152, 154 correspond to the locations of the contact pads 142 for receiving the light emitters 130 once the fence 150 is mounted.

It is understood that the fence 150 may have a wide variety of other configurations in further embodiments. In general the fence may have a shape so that it covers at least some of the surface mounted, electromagnetic radiating components from the first set of electronic components, while having one or more openings or spaces to allow top-down mounting of the components from the second set of components on the PCB 124.

The configuration of the PCB 124 for receiving the first and second set of electronic components may vary greatly in different embodiments, and the configuration of the fence 150 may vary accordingly. In one such further embodiment, the widths of one or more of the portions 150a, 150b and/or 150c may vary to increase or decrease the size of one or both openings 152, 154. In another such further embodiment including a single light emitter 130 instead of the two shown in the figures, one of the openings 152, 154 may be omitted from the fence 150 altogether.

The fence 150 may have edges 156 which extend at an angle down from a major planar surface of the fence 150. It is the edges 156 (or portions of the edges 156) that may be surface mounted to contact pads on the PCB 124, for example by soldering. The height of the edges 156 (i.e., how far the edges 156 extend from a major planar surface of the fence 150) defines how high the fence extends above the surface of the PCB 124.

In one embodiment, a surface of the fence (150c, FIG. 9) facing the substrate when the fence is mounted may be provided at a height of the tallest component of the driver circuitry 134 beneath the fence, plus some predefined clearance that includes any relevant manufacturing tolerances. This clearance may range from nothing (the fence lies in contact with the tallest component of the driver circuitry 134) to about 150 microns (μm), though the clearance could be greater than that in further embodiments.

Thus, the height of the EMI shield 140 above the PCB 124 is equal to the height of the surface 150c above the PCB 124, plus the thicknesses of the fence 150 and cover 160. As explained below, the cover may be a flat, planar plate. In embodiments, the fence 150 and cover 160 may each have thicknesses of between 100 to 150 μm, though one or both may be thicker or thinner than that in further examples. This provides an overall height of the EMI shield above the tallest component beneath the fence 150 of 200 μm to 450 μm, though the EMI shield 140 may be at a height which is greater or smaller than this in further embodiments. This provides an EMI shield 140 having a lower profile above the PCB 124 than is known in the prior art. Prior art EMI shields include mechanical clamps for mounting on the PCB, which mechanical clamps result in a profile above the PCB that is larger than 150 μm.

The fence 150 may be formed of a variety of materials that shield EMI, including by absorbing and/or reflecting EMI. In embodiments, the fence may for example be formed of Nickel plated Aluminum, Nickel plated Copper, or other conductive materials that do not oxidize or have a low rate of oxidation.

The first set of electronic components may be surface mounted in step 200 and reflowed in step 202, and then the fence 150 may be surface mounted over at least some of the first set of electronic components in step 206 and reflowed in step 208. In further embodiments, step 202 may be omitted so that the first set of electronic components may be surface mounted in step 200, the fence 150 may be surface mounted over at least some of the first set of electronic components in step 206, and then the solder mounting the first set of electronic components and the fence may be reflowed in step 208. In either event, use of the fence 150 according to embodiments of the present technology provides fabrication efficiencies, in that it may be mounted in the same process, or at least at the same processing stations, as the first set of surface mounted components.

In step 212, the second set of components may be mounted to the PCB 124. As noted above, in embodiments, the second set of components may be one or more electronic components that would be adversely affected during the surface mount and reflow process steps 200 and 202 described above. However, in further embodiments, there may be reasons unrelated to heat sensitivity for affixing the second set of components after the first set of components and fence have been mounted. For example, the second set of component may be affixed to the PCB 124 at a different location than the first set of components.

Additionally, it is conceivable that the second set of components, including for example light emitters 130, be glued to a sub-mount circuit board (not shown), which may in turn be surface mounted to the PCB 124 using heat. The sub-mount may be mounted to the PCB 124 in a second step, after the first set of components and fence are mounted on the PCB 124.

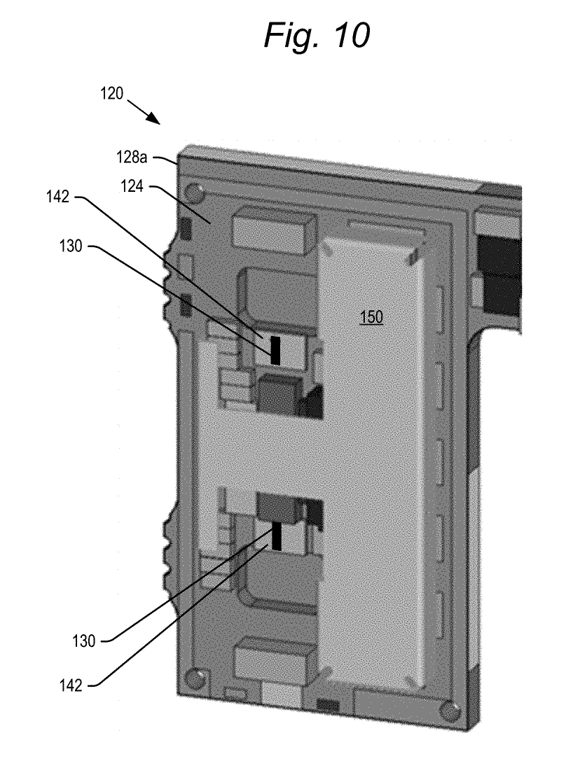

In one embodiment, the second set of components comprise one or more light emitters 130. The one or more light emitters 130 may be mounted to contact pads 142 in step 212 and as shown in FIG. 10, using for example a conductive adhesive. Such adhesives are available for example from Henkel AG & Co., having corporate headquarters in Düsseldorf, Germany. Given the openings 152, 154, the light emitters 130 may be top-down mounted on the contact pads 142 using a pick and place robot. That is, the openings 152, 154 leave room for a robot or tool to transfer the light emitters 130 straight down (or from an angle) onto the contact pads 142.

Thereafter, the adhesive bonding the light emitters may be cured in step 214. Additionally, at least certain light emitters 130, such as laser diodes, are wire bonded to the PCB 124. If the light emitters get wire bonded, they may be wire bonded in step 218. Again, the openings 152, 154 in the fence 150 allow the wire bonding capillary access to bond the light emitters to contact pads on the PCB 124. Where a light emitter 130 is wire bonded to the PCB 124, the light emitter 130 may be adhesively bonded to non-conductive portion on the PCB 124, and may be bonded using a non-conductive adhesive.

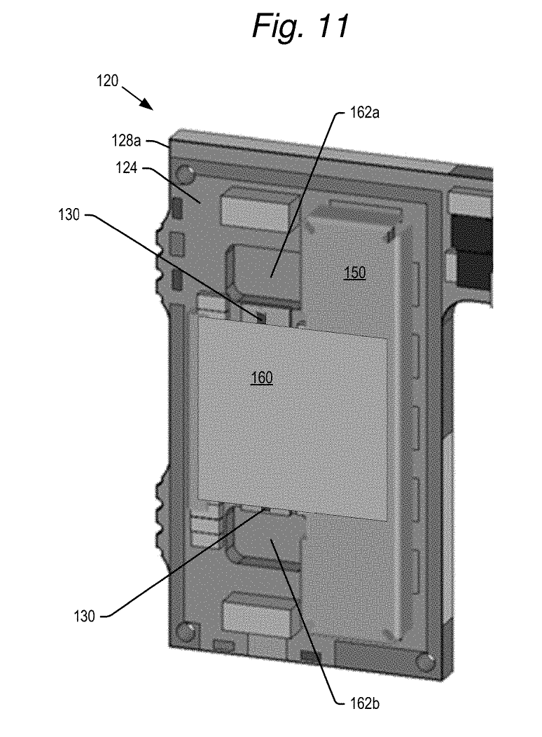

In step 220, a second part of the EMI shield 140—cover 160—may be mounted to the fence 150 as shown in FIG. 11 using an adhesive, such as an epoxy from Henkel AG & Co., mentioned above. The cover 160 may cover at least portions of the light emitters 130, and portions of the first set of electrical components not covered by fence 150, to prevent EMI from these components. The adhesive used may be electrically conductive so that the cover 160 may be grounded to the fence 150. The adhesive may be applied between the cover 160 and fence 150 at one or more of the base portion, transverse portion and/or elongate portion of the fence 150. The adhesive material is also chosen to as to minimize any corrosion mechanisms between the fence and the cover. Instead of an adhesive, other affixation methods that do not use heat may be employed, such as for example screwing or bolting the cover 160 to the fence 150.

The cover 160 is shown with a rectangular shape in FIG. 11. However, it is understood that cover 160 may have a variety of other shapes in further embodiments. The fence may be a planar, flat plate, having a thickness of 25-125 μm, though it may be thinner or thicker than that in further embodiments. The cover 160 may be formed of a variety of materials that shield EMI, including by absorbing and/or reflecting EMI. In embodiments, the cover 160 may be formed of the same material as the fence 150, for example of Nickel plated Aluminum, Nickel plated Copper, or other conductive materials that do not oxidize or have a low rate of oxidation.

In the embodiment shown in FIG. 11, the light emitters 130 may be laser diodes that emit light in a plane parallel to the surface of the PCB 124. The light emitter 130 on the top of FIG. 11 may emit light upward toward a recess 162a, which includes mirrors (not shown) for redirecting the light outward away from the PCB 124. The light emitter 130 on the bottom of FIG. 11 may emit light downward toward a recess 162b, which also includes mirrors (not shown) for redirecting the light outward away from the PCB 124.

As noted, given the heat sensitivity of a light emitter such as a laser diode, the electronic components of the depth sensor 120 may be assembled in a two-step process as described above. First, components are surface mounted to the PCB 124, then the light emitter may be glued to the PCB 124 using an epoxy or other adhesive. The present technology is compatible with such a two-step process in that the fence may be surface mounted to the PCB 124 with the first set of surface mounted components, and then the cover may be glued to the fence using an epoxy or other adhesive.

Additionally, the fence and cover of the present technology are compatible with an electronic, light emitting device where EMI shielding is required, without the EMI shield interfering or blocking the emitted light. The opening(s) left in the shield allow light from the light emitters to travel unimpeded from the depth sensor 120.

In embodiments, the EMI shield 140 including the fence and cover may having openings of about 1 mm, through which the light from the light emitters may radiate. At openings of these sizes, the EMI shield 140 may block EMI down to about 2 GHz. However, it is understood that the EMI shield 140 may have openings of other sizes and block EMI from about 50 MHz to 8 Ghz, though the range of frequencies blocked may be above or below this range in further embodiments.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims. It is intended that the scope of the invention be defined by the claims appended hereto.

We claim:

1. A system for shielding EMI from a device having a first set of one or more components mounted to a substrate using a first heat-bonding material and a second set of one or more components mounted to the substrate, the system comprising:
a fence mounted to the substrate using a second heat-bonding material and covering at least a portion of the first set of one or more components; and
a cover mounted to the fence using an adhesive and covering at least a portion of the second set of one or more components.

2. The system of claim 1, wherein the fence includes portions which define one or more openings in the fence, the openings allowing mounting of the second set of one or more components.

3. The system of claim 2, wherein the one or more openings allow top down mounting of the second set of one or more components through the one or more openings.

4. The system of claim 2, wherein the one or more openings allow wire bonding of the second set of one or more components to the substrate through the one or more openings.

5. The system of claim 1, wherein the second set of one or more components comprise a light emitter.

6. The system of claim 5, wherein the fence and cover together comprise one or more openings allowing light from the light emitter to radiate from the device unimpeded.

7. The system of claim 1, wherein the fence comprises downwardly extending edges mounted to the substrate using the heat-bonding material to support a surface of the fence facing the substrate at a height of the tallest component of the first set of components plus a predefined clearance.

8. The system of claim 7, wherein the cover is a planar plate, and a maximum height of the fence and cover together above the substrate is equal to a height of the surface of the fence above the substrate plus thicknesses of the fence and cover.

9. The system of claim 1, wherein the at least one of the fence and cover are formed from one of Nickel plated Aluminum and Nickel plated Copper.

10. The system of claim 1, wherein the first and second heat-bonding materials are the same.

11. The system of claim 1, wherein the second set of components is mounted to the substrate using the same adhesive as the adhesive used to mount the cover to the fence.

12. A system for shielding EMI from a light emitting device having a first set of one or more components mounted to a substrate using a first heat-bonding material and a second set of one or more components comprising a light emitter mounted to the substrate using a first adhesive, the system comprising:
a fence mounted to the substrate using a heat-bonding material and covering at least a portion of the first set of one or more components, the fence including portions defining one or more openings through which the light emitter is mounted to the substrate; and
a cover mounted to the fence using an adhesive and covering at least a portion of the light emitter while allowing light to radiate from the device without impairment.

13. The system of claim 12, wherein the light emitter comprises a laser diode.

14. The system of claim 13, wherein the one or more openings allow top down mounting of the laser diode through the one or more openings.

15. The system of claim 13, wherein the one or more openings allow wire bonding of the laser diode to the substrate through the one or more openings.

16. The system of claim 1, wherein the fence and cover together have a maximum height above the substrate equal to a height of the fence above the substrate plus thicknesses of the fence and cover.

17. A method of forming an EMI shield in a depth sensor for a head mounted display device, comprising:
(a) surface mounting laser diode driver circuitry on a substrate;
(b) surface mounting a fence over at least a portion of the driver circuitry, the fence including portions defining one or more openings in the fence;
(c) mounting a laser diode to the substrate using a first adhesive, through an opening of the one or more openings in the fence; and
(d) mounting a cover to the fence using a second adhesive, the plate covering at least a portion of the laser diode while allowing unimpeded emission of light from the laser diode.

18. The method of claim 17, wherein the driver circuitry and fence are surface mounted to the substrate using solder and a reflow process.

19. The method of claim 17, wherein steps (a) and (b) are performed in the same process.

20. The method of claim 17, wherein said step (d) comprises the step of mounting the cover to the fence using a conductive adhesive.
